(19) United States
(12) Patent Application Publication
(10) Pub. No.: US 2010/0128453 A1
(43) Pub. Date: May 27, 2010

(54) TUNER

(75) Inventors: Yeow Teng Toh, Singapore (SG); Kam Choon Kwong, Singapore (SG); James Chua, Singapore (SG); Swee Hua Heng, Singapore (SG)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/597,928

(22) PCT Filed: Apr. 29, 2008
(86) PCT No.: PCT/IB08/51655

§ 371 Date: Oct. 28, 2009

(30) Foreign Application Priority Data
May 4, 2007 (EP) 07107525.3

(51) Int. Cl. H05K 9/00; H04B 1/10

(52) U.S. Cl. 361/816

(57) ABSTRACT

A tuner is disclosed which overcomes a problem related to leakage currents within a tuner associated with increased miniaturization. The tuner includes an oscillator and a cover. The cover includes a barrier region, typically in the form of a slot or an air gap, which impedes the propagation of leakage currents, in the form of eddy currents induced from the oscillator, along the cover from the oscillator region to other components in the tuner, and in particular to the input or output connectors.

### FIELD OF THE INVENTION

This invention relates to tuners, and particularly to radio frequency tuner modules for radio or television reception, through either analogue or digital signals. The invention has particular, but not exclusive application to flat screen televisions, digital or cable set top boxes, mobile telephones and other handheld devices.

### BACKGROUND OF THE INVENTION

A tuner module typically comprises an oscillator and an input connector such as an RF aerial jack, often combined with baseband processing circuitry, for processing the received signals from the input connector. Such tuners are typically provided with a casing or shielding. The casing provides physical protection for the components and a low impedance high frequency ground plane, as well as electrical protection from the external environment. In order to provide effective shielding, the casing is typically made of electrically conducting material (usually sheet metal), and is tied electrically to ground through grounding pads. U.S. Pat. No. 5,438,690 to Tsukuda shows an example of a tuner circuit substrate, including a shield case covering the region for the high frequency amplifying circuit, the mixing circuit, and the local oscillating circuit.

However, applicants have found in testing miniaturized tuners that the performance of the tuner is degraded. In fact, it was found that the performance of the tuner can be affected to such an extent that design release specifications or targets could not be satisfied across the full frequency response range.

There exists therefore a desire to miniaturize such modules whilst ensuring specification performance levels are attained.

### SUMMARY OF THE INVENTION

According to an aspect of the invention, there is provided a tuner comprising at least one oscillator and an electrically conducting casing, which casing comprises a first region for the at least one oscillator, a second region and a third region located between the first and the second region, wherein the third region is adapted to restrict the propagation of eddy currents from the first region to the second region.

This aspect is based on the realization by the inventors, that the miniaturization has the consequence that the separation between the components, and between the components and the casing, is reduced. In particular, the proximity between the oscillator and the casing resulted in a surprising and unforeseen increase in unwanted internally induced eddy currents within the casing.

Hence, owing to the recognition of this problem, a tuner according to the invention recited above is provided. In such a tuner, the proximity effects of miniaturization are reduced, enabling the attainment of performance to acceptable specifications for release, despite smaller form factors than previously available.

In an embodiment, there is an input connector located in the second region.

Advantageously, in this embodiment the adaptation of the third region comprises non-conducting material.

Alternatively, in another embodiment, the adaptation of the third region comprises an air gap.

In another embodiment, the third region comprises at least one slot.

Advantageously, this slot is rectangular, having a width W between the first region and the second region.

The width W is advantageously in the range of around 0.3 to around 0.5 mm.

Advantageously, the third region completely separates the first region and the second region.

In yet a further embodiment the casing comprises a plurality of first regions for a plurality of oscillators, and the third region is adapted to restrict the propagation of eddy currents between the plurality of first regions, and between the first regions and the second region.

These and other aspects of the invention will be apparent from and elucidated with reference to the embodiments described hereinafter.

### BRIEF DESCRIPTION OF DRAWINGS

FIG. 1 shows a schematic section through a tuner;

FIG. 2 diagrammatically illustrates a tuner in operation, according to one embodiment of the invention;

FIG. 3 illustrates an embodiment of the invention particularly appropriate for “many in one” tuners; and

FIG. 4 is a measurement graph comparing the oscillator leakage of a tuner according to an embodiment of the invention, with a conventional tuner.

### DETAILED DESCRIPTION OF EMBODIMENTS

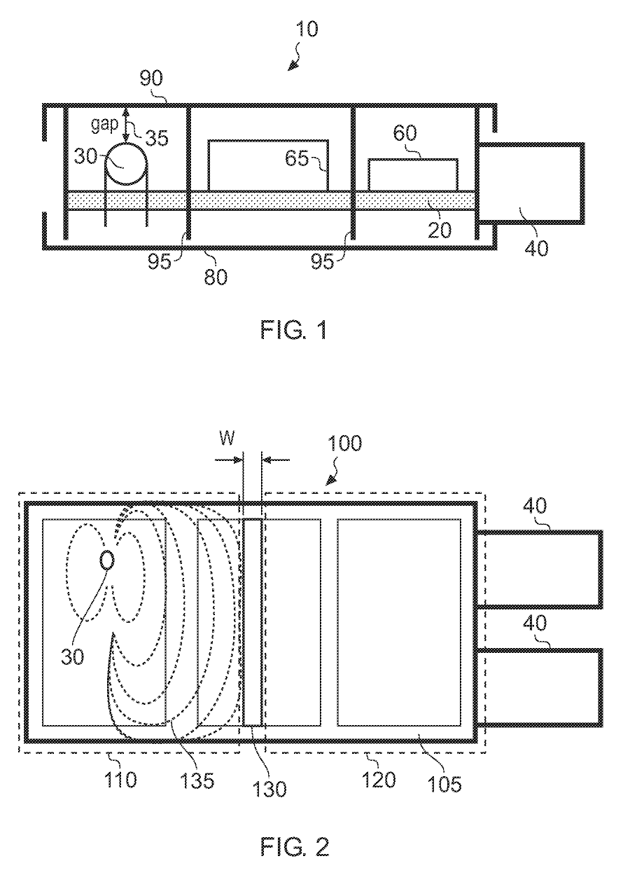

FIG. 1 shows a schematic section through a tuner module 10. The module has a substrate 20, on which are mounted various components. Towards one end of the module is located an oscillator coil 30. The oscillator coil acts as the local oscillator for the super-heterodyne receiver, in order to provide frequency conversion, prior to signal processing in the baseband. Towards the opposite end of the module, is located an input connector, which as shown here is a splitter aerial 40. Between the aerial 40 and the oscillator 30 are an input filter sub-section 60 and a bandpass filter sub-section 65. The components forming the tuner circuit are protected by a casing, which as shown here has a bottom section 80 and a top section 90. Typically, the casing further includes thick metal barriers 95, in order to better contain lateral radiation within the tuner module, and limit propagation of interference or leakage from the oscillator to the other components or subsections.

Typical dimensions for a tuner module 10 as described above, and such as the UV1300 module supplied by NXP Semiconductors, are 53 mm in length by 43 mm in width and 13 mm in height—for which the total module volume is around 30 cm³. However, modern tuner modules are desirably smaller, typically with dimensions of 30 mm length by 30 mm width by 10 mm height, to result in a module volume around 9 cm³

With increasing miniaturization, the location of the components within the module becomes increasingly important. At a certain level of miniaturization, the oscillator coil becomes sufficiently proximate to the cover, to induce eddy currents within the cover. These eddy currents form a leakage path from the oscillator. In larger conventional tuners, the level of induced current is sufficiently small to be negligible. However, the inventors have discovered that, with increasing miniaturization of the tuner devices, the induced current has a significant impact on performance. In other words, with increasing miniaturization, the gap 35 between the oscillator coil and the closest part of the conductive cover becomes small enough to result in detectable and significant eddy currents being induced in the cover. For example, the reduction in volume from 30 cm³ to 9 cm³ described above has resulted in significantly worsened oscillator leakage (see FIG. 4 to be described shortly).

In FIG. 2 is shown a plan view of a tuner 100 according to a first embodiment of the invention. The upper casing 105 has a first region 110 (the general outline of which is depicted by a dashed line), within which is housed the oscillator 30. A second region 120 (also generally depicted by a dashed line), is at the end remote from the oscillator, and is located at, or over, the aerial connector 40, the aerial connector being shown here as a splitter aerial having an input and an output connection socket. Between the first region 110 and the second region 120 is located a third region 130. In this embodiment the third region is a slot in the cover, forming an air gap. The slot has width W.

During the operation of this device, the propagation of eddy currents (shown schematically as dashed lines 135), is impeded by the slot 130. Thus the eddy currents forming the oscillator leakage paths are to a greater extent restricted to the first region of the cover. The level of leakage reaching the input connectors in particular is significantly reduced, compared with that measured on a similar device but without the third region.

In this embodiment, the third region slot is rectangular, with a width W, preferably between about 0.3 mm and 0.5 mm, although widths from about 0.1 mm upwards are possible. Advantageously, the width of the slot is sufficiently narrow to prevent, to a large degree, emission issues from the slot, and to not disrupt to too great an extent the shielding effect and immunity from the external environment, which is provided by the cover. Whilst the inventors recognize that there is a technical prejudice in inclusion of any slot or air gap in a casing that has a prime function of physical and electrical shielding, it was found that a design balance is possible between this disadvantage, and the benefits to be gained by reducing the eddy currents. With such a slot as shown, the thickness is preferably sufficiently large (whilst still being functional as an impediment to eddy currents) to be conveniently manufacturable by a hard tool, that is by a tool which suffers from only limited wear in use, and thus is suitable for mass production of the slot. The width range mentioned above has been found to provide a convenient balance between the electromagnetic compatibility (EMC) performance and industrial hard-tooling capability.

The slot shown is an air gap. However, it will be immediately apparent that any other non-conducting medium may be used in place of an air gap, for instance an insulating adhesive strip may be utilized, or a plastic filler material. In these latter cases, advantageously the components inside the casing will be protected from the physical environment.

Further, as shown in this embodiment, the third region is a rectangular slot. However, there is no limitation that the region is rectangular, or even that the edges of the regions are straight. For instance, the slot could have a zig-zag or curved profile, provided that is it effective to substantially reduce the propagation of eddy currents between the first and second region. More-over, the exact location of the third region is not critical for the operation of the device. Although the region is shown broadly centrally on the module, it may be beneficial to locate it closer to either the oscillator, or the input connectors.

Although the third region is described as non-conducting, the skilled man will immediately appreciate that this term is used purposively, to indicate that the region acts as an effective barrier to the propagation of leakage currents in the cover. Thus, for instance, a conducting medium having a sufficiently high resistivity at the appropriate RF frequency to effectively dampen the leakage signal and thus provide a barrier to propagation would fall within the scope of the invention. Further, the invention does not require that there is an absolute absence of leakage current in the second region, but merely that the third region acts as an effective barrier to disrupt the eddy currents and to reduce the impact of leakage current on the device. Also, the skilled man will appreciate that the full range of geometrical variations described in relation to an air gap above will be applicable in relation to non-conducting materials. Indeed, since some such materials provide for increased mechanical strength relative to an air gap, a greater design freedom may be available for the physical arrangement of the third region, when using such materials, relative to an air gap.

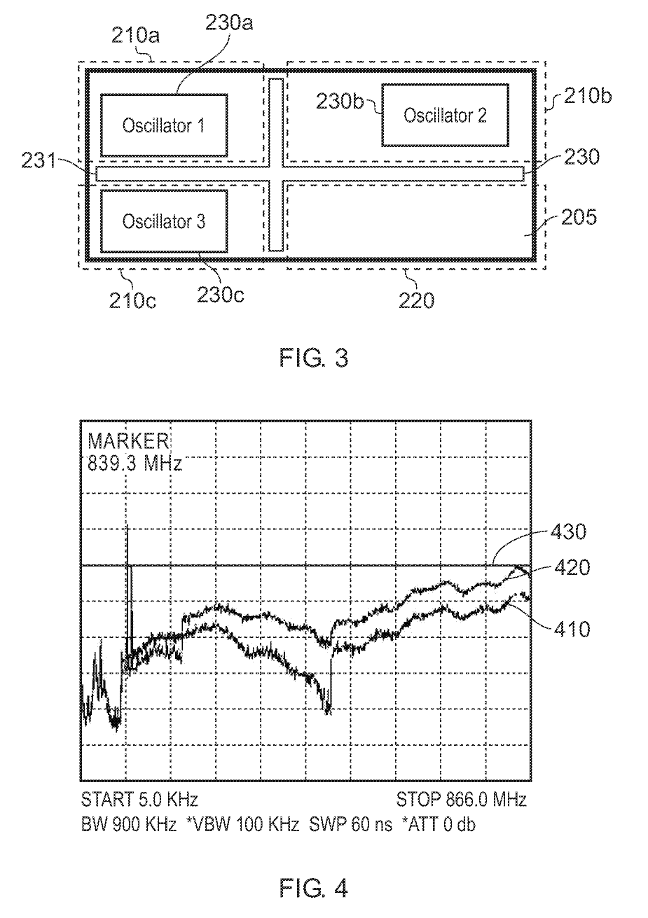

A further embodiment of the invention is shown in FIG. 3. This depicts a layout for a “many-in-1” type of tuner, which is becoming increasingly popular and important. This tuner has multiple oscillators 230—as shown there are three oscillators 230a, 230b and 230c, associated with respective first regions 210a, 210b and 210c of the top cover 205. In this embodiment the oscillators are each in a separate corresponding first region 210, however, it may be appropriate to include more than one oscillator within one region. A second region 220 is associated with other components of the tuner, including the input connector or aerial (not shown). The first regions and the second region are each separated from each other by the third region 230. As shown, the third region includes an air gap in the form of a slot; however, as discussed in relation to the previous embodiment, it will be equally possible to provide the third region as a suitable non-conducting material.

As shown in FIG. 3, the third region is in the form of a continuous slot having a cruciform shape. However, it is equally possible to provide the third region as a discontinuous region; for instance, the region could take the form of a “T” shaped slot to form a barrier between first region 210c and second region 220 and between each of these regions and the two first regions 210a and 210b; a further rectangular slot, not directly joined to the T shaped slot, may be provided act as to a barrier to impede leakage between the two first regions 210a and 210b.

As shown in FIG. 3, the third region may extend to the edge of the cover (for instance, at 231). The third region may extend fully across the cover (not shown), to effectively separate the cover into two (or more) sections. Although this will result in an increased parts count and may lead to reduction in mechanical strength of the cover, it may provide for a higher level of isolation between the regions, and thus be beneficial. Further, although in the foregoing, reference has been made to the third region as a single slot or barrier, a series of slots or barriers may be provided, each of which extends across part of the cover. This may result in improved mechanical strength, relative to a single slot. This is particularly useful, in the case of the third region being an air gap.

FIG. 4 is a graph, showing the oscillator leakage from a tuner embodying the invention (lower trace 410), in comparison with a similar conventional tuner having the same form factor, but which does not embody the invention (upper trace 420). The X-axis or abscissa represents the Frequency, over a range from 5 MHz to 866 MHz, and the Y-axis or ordinate represents the leakage from the oscillator, as measured in the RF output connector. The solid line 430 represents a typical maximum leakage observed on the conventional tuner, of 30 dBuV. The graph illustrates that, for this particular tuner, inclusion of a slot (in this instance an air gap), may reduce leakage across the RF range of interest.

Reference has been made to the top cover, in the embodiments discussed above. However, in tuners having separate top and bottom covers (such a covers 90 and 80), similar leakage paths can result from eddy currents propagating in the bottom cover. The invention thus extends to the inclusion of third regions in both top and bottom covers. Similarly, the invention extends to third regions in both top and bottom faces of wrap-around, or one-part covers or housings.

From reading the present disclosure, other variations and modifications will be apparent to the skilled person. Such variations and modifications may involve equivalent and other features which are already known in the art of tuners and which may be used instead of, or in addition to, features already described herein.

Although the appended claims are directed to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination.

The applicant hereby gives notice that new claims may be formulated to such features and/or combinations of such features during the prosecution of the present application or of any further application derived therefrom.

For the sake of completeness it is also stated that the term “comprising” does not exclude other elements or steps, the term “a” or “an” does not exclude a plurality, and reference signs in the claims shall not be construed as limiting the scope of the claims.

1. A tuner comprising
at least one oscillator; and
an electrically conducting casing, which casing comprises a first region for the at least one oscillator, a second region and a third region located between the first and the second region,
wherein the third region is adapted to restrict the propagation of eddy currents from the first region to the second region.

2. A tuner as claimed in claim 1 further comprising an input connector located in the second region.

3. A tuner as claimed in claim 1 wherein the the third region comprises non-conducting material.

4. A tuner as claimed in claim 1 wherein the adaptation of the third region comprises an air gap.

5. A tuner as claimed in claim 1 wherein the third region comprises at least one slot.

6. A tuner as claimed in claim 5 wherein the at least one slot is rectangular, having a width W between the first region and the second region.

7. A tuner as claimed in claim 6 wherein the width W of the at least one slot is between about 0.3 mm and about 0.5 mm.

8. A tuner as claimed in claim 1 wherein the third region completely separates the first region and the second region.

9. A tuner as claimed in claim 1, wherein the casing comprises a plurality of first regions for a plurality of oscillators, and the third region is adapted to restrict the propagation of eddy currents between the plurality of first regions, and between the first regions and the second region.

10. (canceled)
